(19) United States
(12) Patent Application Publication
(10) Pub. No.: US 2023/0416918 A1
(43) Pub. Date: Dec. 28, 2023

(54) PEDESTAL INCLUDING SEAL

(71) Applicant: LAM RESEARCH CORPORATION, Fremont, CA (US)

(72) Inventor: Christopher GAGE, Truckee, CA (US)

(21) Appl. No.: 18/035,200

(22) PCT Filed: Nov. 9, 2021
(86) PCT No.: PCT/US2021/072302

§ 371 Date: May 3, 2023

Related U.S. Application Data
(60) Provisional application No. 63/115,419, filed on Nov. 18, 2020.

(51) Int. Cl. C23C 16/458; C23C 16/455; C23C 16/44

(52) U.S. Cl. CPC C23C 16/4585; C23C 16/45544; C23C 16/4408; C23C 16/4409; C23C 16/4586

(57) ABSTRACT

A pedestal assembly for a substrate processing system includes a pedestal including a pedestal plate with a plurality of gas through holes and a stem extending downwardly from the pedestal plate. The plurality of gas through holes extend from a first surface of the pedestal plate to a second surface of the pedestal plate at a location radially outside of the stem. A collar is arranged around the stem of the pedestal and openings of the plurality of gas through holes are located on the second surface of the pedestal. The collar defines an annular volume between the collar and the stem of the pedestal. An upwardly facing surface of the collar makes a surface-to-surface seal with the second surface of the pedestal.

### CROSS-REFERENCE TO RELATED APPLICATIONS

This application claims the benefit of U.S. Provisional Application No. 63/115,419, filed on Nov. 18, 2020. The entire disclosure of the application referenced above is incorporated herein by reference.

### FIELD

The present disclosure relates to substrate processing systems and more particularly to a pedestal including a seal.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

There are several types of atomic layer deposition (ALD) that may be used to deposit thin film on to a substrate. Examples of ALD include plasma-enhanced ALD (PEALD) and thermal ALD (T-ALD). Substrate processing system for performing T-ALD typically include a heated pedestal upon which a substrate rests during processing.

### SUMMARY

A pedestal assembly for a substrate processing system includes a pedestal including a pedestal plate with a plurality of gas through holes and a stem extending from the pedestal plate. The plurality of gas through holes extend from a first surface of the pedestal plate to a second surface of the pedestal plate at a location radially outside of the stem. A collar is arranged around the stem of the pedestal and openings of the plurality of gas through holes are located on the second surface of the pedestal. The collar defines an annular volume between the collar and the stem of the pedestal. An upwardly facing surface of the collar makes a surface-to-surface seal with the second surface of the pedestal.

In other features, a pedestal support structure is attached to a distal end of the stem. An “0”-ring is located between the distal end of the stem and the pedestal support structure. The stem of the pedestal includes a flange extending radially outwardly at a bottom edge thereof and a pedestal support structure attached to the flange of the stem. The collar is attached to the pedestal support structure. An “0”-ring is located between a distal end of the collar and the pedestal support structure.

In other features, the surface-to-surface seal includes a flat-to-flat seal.

In other features, the pedestal support structure includes a cylindrical body with a side wall. A vertical bore in the side wall defines a gas channel. The gas channel fluidly communicates with the annular volume and the plurality of gas through holes. The pedestal support structure includes a cylindrical body defining an inner cavity and a flange extending radially outwardly from an upper surface of the cylindrical body. One or more clamps connect a flange located on a distal end of the stem to the flange extending radially outwardly from the cylindrical body of the pedestal support structure.

In other features, the collar includes first and second flanges located on upper and lower surfaces thereof, respectively. A clamp is arranged around the flange of the pedestal support structure and the second flange of the collar. An “0”-ring is located between a second surface of the second flange and an upper surface of the clamp.

In other features, a first valve is configured to selectively connect the gas channel, the annular volume and the gas through holes to a vacuum source. A controller is configured to selectively control the first valve to supply vacuum to the gas channel, the annular volume and the gas through holes during processing of a substrate.

In other features, a second valve is configured to selectively connect the gas channel, the annular volume and the gas through holes to a purge gas source. The controller is further configured to selectively control the second valve to purge the gas channel, the annular volume and the gas through holes.

In other features, a valve is configured to selectively connect the gas channel, the annular volume and the gas through holes to a purge gas source. A controller is configured to selectively control the valve to purge the gas channel, the annular volume and the gas through holes. The pedestal is made of ceramic. The pedestal is made of aluminum nitride. The collar is made of ceramic. The collar is made of alumina.

In other features, a second surface of the pedestal plate and an upper surface of the stem are polished to a surface roughness (Ra) that is less than or equal to 20 micro inches. A second surface of the pedestal plate and an upper surface of the stem are polished to a surface roughness (Ra) that is less than or equal to 16 micro inches. A second surface of the pedestal plate and an upper surface of the stem are polished to a surface roughness (Ra) in a range from 3 to 8 micro inches.

A pedestal assembly includes a pedestal with a pedestal plate including a plurality of gas through holes and a stem extending from the pedestal plate. The plurality of gas through holes extend from a first surface of the pedestal plate to a second surface of the pedestal plate. A collar is arranged around the stem of the pedestal. The pedestal plate has a first diameter, the stem has a second diameter that is less than the first diameter, and the collar has a third diameter that is less than the first diameter and greater than the second diameter. The plurality of gas through holes are arranged in a first region of the pedestal plate that is defined between the second diameter and third diameter. The gas through holes are not located in a second region outside of the first region and the third region located inside of the first region. The collar defines an annular volume between the collar and the stem of the pedestal.

In other features, a first surface of the collar makes a surface-to-surface seal with the second surface of the pedestal. A pedestal support structure is attached to a distal end of the stem. An “O”-ring is located between the distal end of the stem and the pedestal support structure. A second surface of the pedestal plate and an upper surface of the stem are polished to a surface roughness (Ra) that is less than or equal to 20 micro inches. A second surface of the pedestal plate and an upper surface of the stem are polished to a surface roughness (Ra) that is less than or equal to 16 micro inches. A second surface of the pedestal plate and an upper surface of the stem are polished to a surface roughness (Ra) in a range from 3 to 8 micro inches.

In other features, the surface-to-surface seal comprises a flat-to-flat seal. The plurality of gas through holes are arranged in a circle in the first region.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system including a pedestal with a seal according to the present disclosure;

FIG. 2 is a plan view of a first surface of an example of the pedestal according to the present disclosure;

FIG. 3 is a cross-sectional side view of an example of a gas distribution device and the pedestal including the seal according to the present disclosure;

FIG. 4 is a cross-sectional side view of an example of a pedestal support structure including a side wall with a gas channel; and

FIG. 5 is a side cross-sectional view of an example of the pedestal including the seal according to the present disclosure.

In the drawings, reference numbers may be reused to identify similar and/or identical elements.

### DETAILED DESCRIPTION

There are several types of atomic layer deposition (ALD) that may be used to deposit thin film. Examples of ALD include plasma-enhanced ALD (PEALD) and thermal ALD (T-ALD). Each PEALD cycle includes a dose step during which the substrate is exposed to precursor, a purge step, an RF plasma step and a purge step. In T-ALD, the substrate is arranged on a heated pedestal during processing and plasma is not used. Each T-ALD cycle typically involves a first dose step during which the substrate is exposed to a first precursor, a purge step, a second dose step during which the substrate is exposed to a second precursor and a purge step. A monolayer is typically deposited during each ALD cycle. Multiple ALD cycles are performed to deposit a layer with a desired thickness.

While the foregoing description describes a seal system for a pedestal assembly for T-ALD processing, the seal system and pedestal assembly can be used in other substrate processing applications. Delivering gas to high temperature pedestals used in T-ALD is challenging. In some examples, pedestal and substrate temperatures may be in a range from 200° C. to 1000° C., although other process temperatures may be used.

A pedestal assembly includes a pedestal with a pedestal plate and a stem. In some examples, the stem includes a hollow cylindrical portion that extends from the pedestal plate. The pedestal plate includes gas through holes that extend through the pedestal plate to fluidly communicate with an annulus or annular volume around the stem. As used herein, fluidly communicate refers to gas flow from one volume to another volume via a gas channel. A seal system includes a collar abutting a second surface of the pedestal plate and surrounding the stem to create the annular volume.

The collar provides a surface-to-surface seal to a second surface of the pedestal plate. In other words, a one surface of the collar is pressed against another surface of the pedestal to form a seal without welding or otherwise joining the two surfaces or using at the surface-to-surface contact. In some examples, the surface-to-surface seal is located in a single plane and is a flat-to-flat seal. To maintain a sufficient seal, a second surface of the pedestal and a first surface of the collar are polished to a surface roughness sufficient to maintain a desired amount of sealing. In some examples, the flat-to-flat seal includes a ceramic to ceramic seal between the collar and a second surface of the pedestal plate. The flat-to-flat seal does not provide an adequate leakage rate to atmosphere. However, the seal does provide adequate isolation of gas species and pressure differentials for delivery of purge gasses or vacuum inside of the processing chamber as will be described further below.

The collar creates the sealed annular volume around the pedestal stem. In some examples, an “0”-ring arranged at a distal end of the collar provides spring force. In other words, the collar is biased against the second surface of the pedestal plate to create a seal that isolates vacuum clamping from chamber pressures.

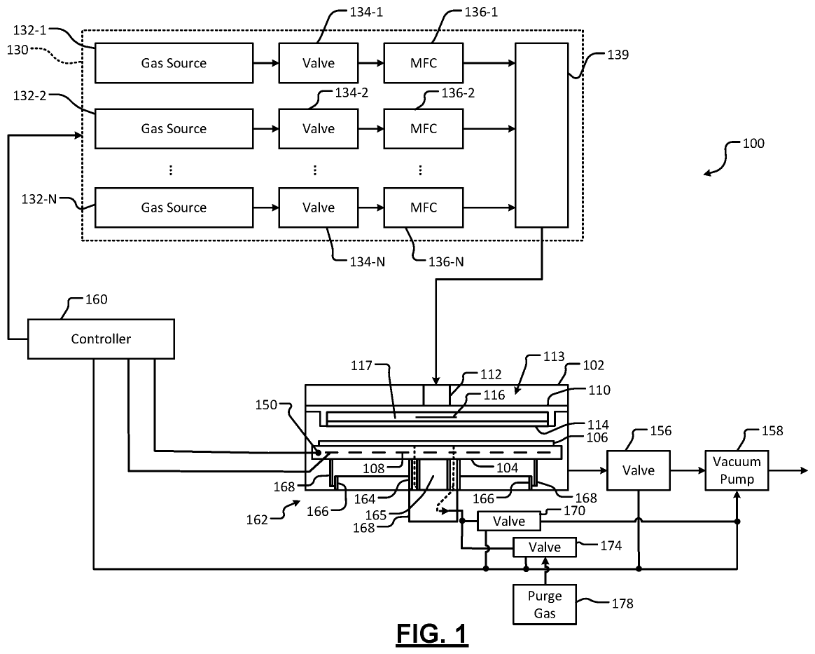

Referring now to FIG. 1, an example of a substrate processing system 100 includes a processing chamber 102 configured to process a substrate. In some examples, the process includes thermal atomic layer deposition (T-ALD). The processing chamber 102 includes side walls, a first surface and a second surface. The processing chamber 102 encloses other components of the substrate processing system 100. During processing, a substrate 106 is arranged on a pedestal 104. One or more heaters 108 (e.g., a heater array) may be disposed in the pedestal 104 to heat the pedestal 104 and the substrate 106 during processing. In some examples, the pedestal 104 is made of ceramic such as aluminum nitride (AlN), alumina or another suitable oxide or non-oxide ceramic material. In other examples, metal materials such as aluminum may be used.

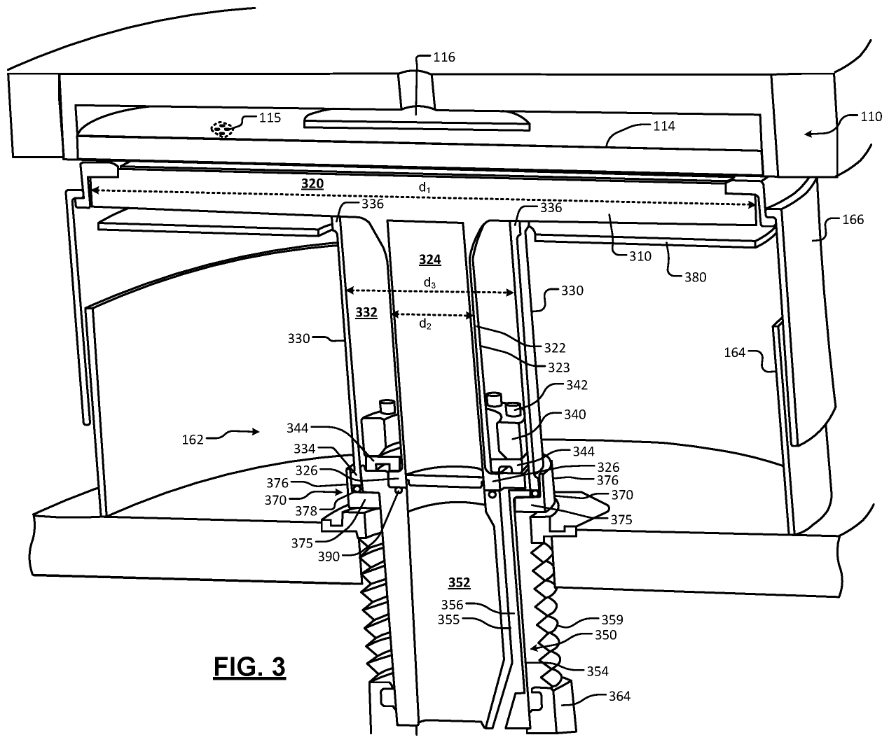

The processing chamber 102 includes a gas distribution device 110 such as a showerhead to introduce and distribute process gases into the processing chamber 102. The gas distribution device (hereinafter showerhead) 110 may include a stem portion 112 including one end connected to a first surface of the processing chamber 102. A base portion 113 of the showerhead 110 is generally cylindrical and extends radially outwardly from an opposite end of the stem portion 112 at a location that is spaced from the first surface of the processing chamber 102. A substrate-facing surface of the base portion 113 of the showerhead 110 includes a faceplate 114. Gas such as carrier gas, inert gas, and precursor flows through the stem portion 112, onto a dispersion plate 116 and into a plenum 117. Gas then flows through a plurality of gas through holes (identified at 115 in FIG. 3) in the faceplate 114 into the processing chamber 102.

A gas delivery system 130 includes one or more gas sources 132-1, 132-2, . . . , and 132-N(collectively, the gas sources 132), where N is an integer greater than zero. The gas sources 132 are connected by valves 134-1, 134-2, . . . , and 134-N(collectively, the valves 134) and mass flow controllers 136-1, 136-2, . . . , and 136-N(collectively, the mass flow controllers 136) to a manifold 139. An output of the manifold 139 is fed to the processing chamber 102. The gas sources 132 may supply process gases, cleaning gases, purge gases, inert gases, precursors, and so on to the processing chamber 102.

A controller 160 controls the components of the substrate processing system 100. The controller 160 may be connected to the heaters 108 and one or more temperature sensor 150 in the pedestal 104. The controller 160 may control power supplied to the heaters 108 based on the sensed temperature to control the temperature of the pedestal 104 and the substrate 106. The heaters 108 may be arranged in one or more zones.

A vacuum pump 158 maintains sub-atmospheric pressure inside the processing chamber 102 during substrate processing. In some examples, the pressure in the processing chamber is maintained in a pressure range from 10 mTorr to 100 Torr. In some examples, the pressure in the processing chamber is maintained in a pressure range from 20 Torr to 40 Torr (e.g. 30 Torr).

A valve 156 is connected to an exhaust port of the processing chamber 102. The valve 156 and the vacuum pump 158 are used to control pressure in the processing chamber 102 and to evacuate reactants from the processing chamber 102 via the valve 156.

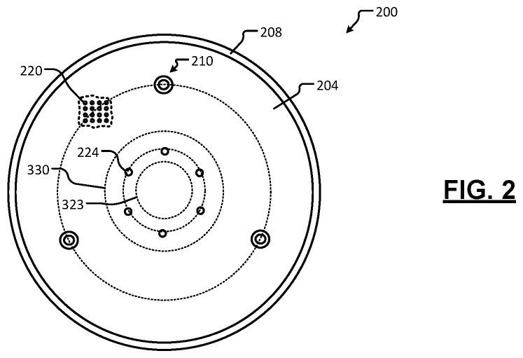

During processing, the substrate 106 is supported on a first surface of the pedestal 104 by vacuum. The pedestal 104 includes a plurality of gas through holes (identified at 224 in FIG. 2) that allow gas to pass from the first surface to the second surface of the pedestal 104.

A seal system 162 maintains a sufficiently tight seal around openings of the plurality of holes 224 located on a second surface of the pedestal 104. The seal system 162 allows vacuum to be maintained to hold the substrate against the pedestal 104 during processing or gases to be delivered through the plurality of holes 224 during purging. The seal system 162 includes a collar 164 arranged around a pedestal stem 165. In some examples, the collar 164 is made of a material with a similar coefficient of thermal expansion (CTE) as the pedestal 104. In some examples, the collar 164 is made of ceramic such as alumina.

Volume between the collar 164 and the pedestal stem 165 is selectively connected by a valve 170 to the vacuum pump 158 or another vacuum source. In some examples, the volume between the collar 164 and the pedestal stem 165 may be selectively connected by a valve 174 to a purge gas source 178. A first cylinder 166 is radially spaced from and surrounds the collar 164 and extends from a second surface of the processing chamber. A second cylinder 168 is radially spaced from and surrounds the first cylinder 166 and extends from a second surface of the pedestal 104. The first cylinder 166 and the second cylinder 168 are configured to allow relative axial movement therebetween, to allow limited gas flow therebetween and to direct gases exiting the interior of the second cylinder 168 in a downward direction.

During operation, the substrate 106 is arranged on the pedestal 104 and the valve 170 is opened to the vacuum pump 158. Vacuum holds the substrate 106 against the pedestal 104. The process is performed on the substrate 106 and then the valve 170 is closed, vacuum is turned off and the substrate 106 is removed. A purge step may be performed between some substrate processing cycles and/or during maintenance by opening the valve 174 (with the valve 170 closed) to flow purge gas through the volume between the collar 164 and the pedestal stem 165 and the plurality of gas through holes 224 in the pedestal 104. The plurality of gas through holes 224 extend from a first surface of the pedestal 104 to a second surface of the pedestal 104.

Referring now to FIG. 2, a pedestal 200 is shown to include a first surface 204 with an outer seal band 208, lift pin holes 210, a plurality of projections or mesas 220 and the plurality of gas through holes 224. The plurality of projections or mesas 220 may be distributed across the first surface 204 at spaced locations to support the substrate in flat, convex, tilted (from one radial edge to an opposite radial edge) or concave positions. In some examples, the outer seal band 208 and the plurality of projections or mesas 220 extend upwardly to a predetermined height above the first surface 204. In some examples, the predetermined height of the projections or mesas 220 may vary. In some examples, the substrate is held flat during processing and the height of the projections may be the same or may vary in various patterns to provide a desired cooling pattern.

Referring now to FIG. 3, a pedestal 310 including the seal system 162 is shown. The pedestal 310 includes a pedestal plate 320 upon which the substrate is supported during processing and a stem portion 322 extending downwardly from the pedestal plate 320. In some examples, the pedestal 310 is made of ceramic. In some examples, the pedestal plate 320 has a flat cylindrical shape. In some examples, the pedestal plate 320 has a first diameter (d₁). In some examples, the stem portion 322 includes a side wall 323 with a second diameter (d₂). In some examples, the side wall 323 extends a predetermined distance. In some examples, the second diameter is less than the first diameter. In some examples, the second diameter is less than or equal to 60%, 50%, 40% or 30% of the first diameter. A flange 326 is located at lower end of the side wall 323. In some examples, the flange 326 extends radially outwardly from the side wall 323. The side wall 323 defines an inner cavity 324.

A collar 330 is spaced from and surrounds the side wall 323 of the stem portion 322 of the pedestal 310. The collar 330 has a third diameter (d₃) and defines an annular volume between an inner surface 332 of the collar 330 and an outer surface of the side wall 323 of the stem portion 322 of the pedestal 310. The collar 330 includes flanges 334 and 336 extending radially outwardly from lower and upper ends thereof, respectively. A lower and radially inner surface of the collar 330 abuts an upper and radially outer surface of a pedestal support structure 350.

In some examples, the gas through holes 224 are arranged in a region of the pedestal plate 320 that is located between the side wall 323 of the stem portion 322 and an inner surface 332 of the collar 330. In some examples, the gas through holes 224 are not located in a first region of the pedestal plate 320 inside of the side wall 323 of the stem portion or outside of the inner surface 332 of the collar 330.

The pedestal support structure 350 has a cylindrical body that is attached below the flange 326 of the pedestal 310 and defines an inner cavity 352. A side wall 354 of the pedestal support structure 350 includes a bore 355 defining a gas channel 356. The gas channel 356 can be connected to the vacuum source to hold the substrate against the pedestal 310 or connected to a purge gas source to purge the pedestal 310 when substrates are removed as described above. A bellows seal 359 provides a flexible seal around the pedestal support structure 350 above a lower support 364.

The bottom of the stem portion 322 of the pedestal 310 is connected to the pedestal support structure 350 using one or more clamps. In some examples, the one or more clamps include clamping rings with an annular or split annular shape. A first clamp 340 is connected by one or more fasteners 342 through a second clamp 344 to a first surface of the pedestal support structure 350. As used herein, the term clamp refers to an annular or arcuate portion that is fastened to another component to hold one or more components together. In some examples, the second clamp 344 has a “C”-shaped cross section (rotated clockwise by 90 degrees).

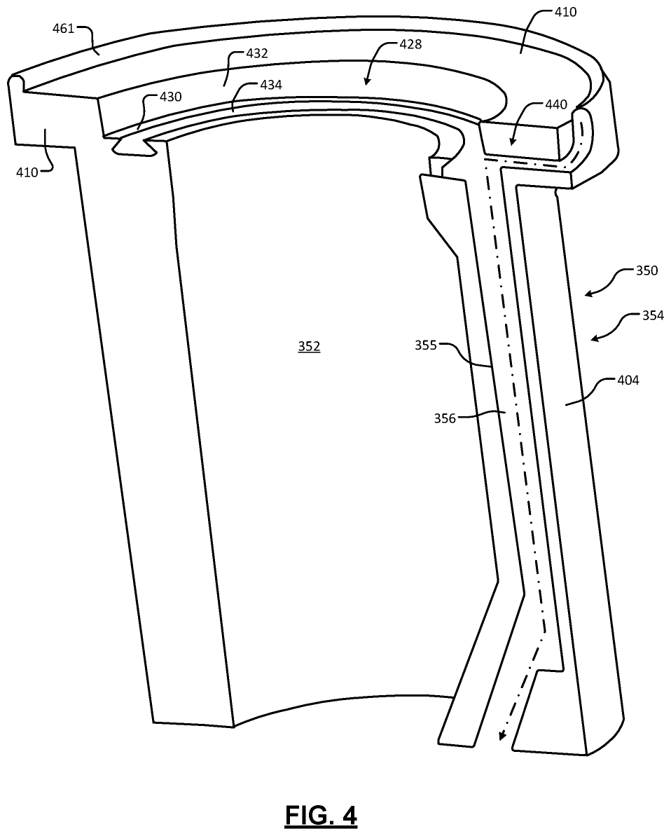

A third clamp 370 is attached to a bottom facing surface of a flange (410 in FIG. 4) of the pedestal support structure 350. In some examples, the third clamp 370 has an “L”-shaped cross-section and includes an upwardly projecting portion 376 and a radially inwardly projecting portion 375. An “0”-ring 378 provides a seal between a second surface of the flange 334 and an upwardly-facing surface of the radially inwardly projecting portion 375. Likewise, an “0”-ring 390 is located between a second surface of the flange 326 and an upwardly-facing surface of the pedestal support structure 350. An annular heat shield 380 is arranged a predetermined distance below the pedestal 310 and includes a central opening wide enough to receive the collar 330 and the stem portion 322 of the pedestal 310.

Referring now to FIG. 4, the pedestal support structure 350 includes a body 404 and a flange 410 extending radially outwardly from an upper portion of the body 404. The side wall 354 of the pedestal support structure 350 includes the bore 355 defining a vertical portion of the gas channel 356 to flow purge gas or supply vacuum. An annular opening 428 formed on a first surface of the flange 410 defines a vertical surface 432 and a horizontal surface 430 extending radially inwardly therefrom. A groove 434 is formed on the horizontal surface 430. The “0”-ring seal 390 may be arranged in the groove 434. A radial bore 440 passes through the flange portion (or another portion of the pedestal support structure 350) and is in fluid communication with the gas channel 356. An annular projection 461 extends upwardly from a radially outer and upper surface of the flange 410.

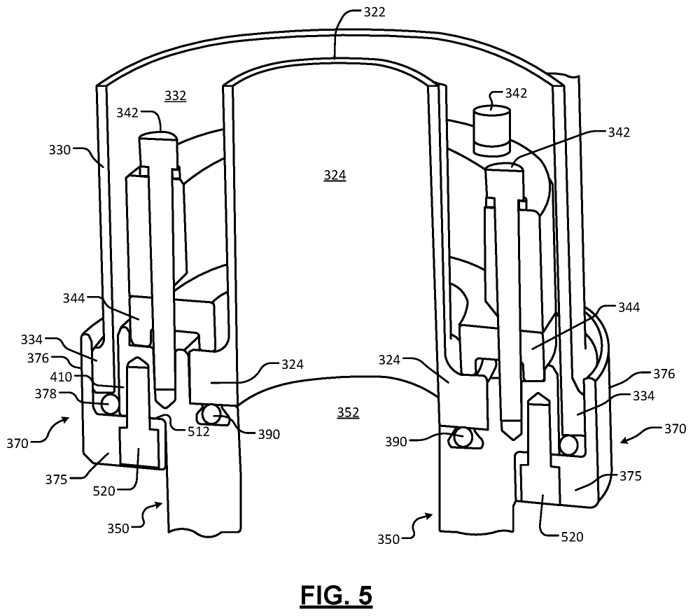

Referring now to FIG. 5, the third clamp 370 is fastened by one or more fasteners 520 to a downwardly-facing surface 512 of the flange 410 of the pedestal support structure 350. The fasteners 342 fasten the first clamp 340 through the second clamp 344 to an upper surface 524 of the flange 410.

As can be appreciated, a surface-to-surface seal is created at an interface between an upper surface of the flange 336 of the collar 330 and a second surface of the pedestal 310. In some examples, the surface-to-surface seal includes a flat-to-flat seal that is created when two flat surfaces are arranged in direct contact without joining the two materials using welding or using a separate seal such as an O-ring. In other examples, the surface-to-surface seal includes complementary, non-planar surfaces. In other words, the abutment of the two surfaces forms the seal. In some examples, the upper surface of the flange 336 of the collar 330 and the second surface of the pedestal 310 are polished to a surface roughness (Ra) in a range from 3 to 20 micro inches. In other examples, the surface roughness is in a range from 3 to 16 micro inches. In other examples, the surface roughness is in a range from 3 to 8 micro inches.

The collar 330 abuts the O-ring 378, which biases the upper surface of the flange 336 of the collar 330 against the second surface of the pedestal 310. Likewise, the “0”-ring seal 390 provides a seal between the second surface of the flange 326 and the upper surface of the pedestal support structure 350.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A pedestal assembly comprising:
a pedestal including a pedestal plate with a plurality of gas through holes and a stem extending from the pedestal plate,
wherein the plurality of gas through holes extend from a first surface of the pedestal plate to a second surface of the pedestal plate at a location radially outside of the stem; and
a collar arranged around the stem of the pedestal and openings of the plurality of gas through holes located on the second surface of the pedestal,
wherein the collar defines an annular volume between an inner surface of the collar and an outer surface of the stem of the pedestal, and
wherein a first surface of the collar makes a surface-to-surface seal with the second surface of the pedestal.

2. The pedestal assembly of claim 1, further comprising a pedestal support structure attached to a distal end of the stem.

3. The pedestal assembly of claim 2, further comprising an “O”-ring located between the distal end of the stem and the pedestal support structure.

4. The pedestal assembly of claim 1, wherein the stem of the pedestal includes a flange extending radially outwardly at a bottom edge thereof and further comprising a pedestal support structure attached to the flange of the stem.

5. The pedestal assembly of claim 2, wherein the collar is attached to the pedestal support structure.

6. The pedestal assembly of claim 5, further comprising an “O”-ring located between a distal end of the collar and the pedestal support structure.

7. The pedestal assembly of claim 2, wherein the pedestal support structure includes a cylindrical body with a side wall, a vertical bore in the side wall defines a gas channel, and the gas channel fluidly communicates with the annular volume and the plurality of gas through holes.

8. The pedestal assembly of claim 2, wherein the pedestal support structure includes a cylindrical body defining an inner cavity and a flange extending radially outwardly from an upper surface of the cylindrical body.

9. The pedestal assembly of claim 8, further comprising one or more clamps connecting a flange located on a distal end of the stem to the flange extending radially outwardly from the cylindrical body of the pedestal support structure.

10. The pedestal assembly of claim 8, wherein the collar includes first and second flanges located on upper and lower surfaces thereof, respectively, and further comprising a clamp arranged around the flange of the pedestal support structure and the second flange of the collar.

11. The pedestal assembly of claim 10, further comprising an “O”-ring located between a second surface of the second flange and an upper surface of the clamp.

12. The pedestal assembly of claim 7, further comprising:
a first valve configured to selectively connect the gas channel, the annular volume and the gas through holes to a vacuum source; and
a controller configured to selectively control the first valve to supply vacuum to the gas channel, the annular volume and the gas through holes during processing of a substrate.

13. The pedestal assembly of claim 12, further comprising a second valve configured to selectively connect the gas channel, the annular volume and the gas through holes to a purge gas source, wherein the controller is further configured to selectively control the second valve to purge the gas channel, the annular volume and the gas through holes.

14. The pedestal assembly of claim 7, further comprising:
a valve configured to selectively connect the gas channel, the annular volume and the gas through holes to a purge gas source; and
a controller configured to selectively control the valve to purge the gas channel, the annular volume and the gas through holes.

15. The pedestal assembly of claim 1, wherein the pedestal is made of ceramic.

16. The pedestal assembly of claim 1, wherein the pedestal is made of aluminum nitride.

17. The pedestal assembly of claim 1, wherein the collar is made of ceramic.

18. The pedestal assembly of claim 1, wherein the collar is made of alumina.

19. The pedestal assembly of claim 1, wherein a second surface of the pedestal plate and an upper surface of the stem are polished to a surface roughness (Rₐ) that is less than or equal to 20 micro inches.

20. The pedestal assembly of claim 1, wherein the surface-to-surface seal comprises a flat-to-flat seal.

21. The pedestal assembly of claim 1, wherein a second surface of the pedestal plate and an upper surface of the stem are polished to a surface roughness (Rₐ) that is less than or equal to 16 micro inches.

22. The pedestal assembly of claim 1, wherein a second surface of the pedestal plate and an upper surface of the stem are polished to a surface roughness (Rₐ) in a range from 3 to 8 micro inches.

23. A pedestal assembly comprising:
a pedestal including a pedestal plate with a plurality of gas through holes and a stem extending from the pedestal plate,
wherein the plurality of gas through holes extend from a first surface of the pedestal plate to a second surface of the pedestal plate; and
a collar arranged around the stem of the pedestal,
wherein the pedestal plate has a first diameter, the stem has a second diameter that is less than the first diameter, and the collar has a third diameter that is less than the first diameter and greater than the second diameter,
wherein the plurality of gas through holes are arranged in a first region of the pedestal plate that is defined between the second diameter and third diameter,
wherein the plurality of gas through holes are not located in a second region outside of the first region and a third region located inside of the first region, and
wherein the collar defines an annular volume between the collar and the stem of the pedestal.

24. The pedestal assembly of claim 23, wherein a first surface of the collar makes a surface-to-surface seal with the second surface of the pedestal.

25. The pedestal assembly of claim 23, further comprising a pedestal support structure attached to a distal end of the stem.

26. The pedestal assembly of claim 25, further comprising an “O”-ring located between the distal end of the stem and the pedestal support structure.

27. The pedestal assembly of claim 23, wherein a second surface of the pedestal plate and an upper surface of the stem are polished to a surface roughness (Rₐ) that is less than or equal to 20 micro inches.

28. The pedestal assembly of claim 23, wherein a second surface of the pedestal plate and an upper surface of the stem are polished to a surface roughness (Rₐ) that is less than or equal to 16 micro inches.

29. The pedestal assembly of claim 23, wherein a second surface of the pedestal plate and an upper surface of the stem are polished to a surface roughness (Rₐ) in a range from 3 to 8 micro inches.

30. The pedestal assembly of claim 24, wherein the surface-to-surface seal comprises a flat-to-flat seal.

31. The pedestal assembly of claim 23, wherein the plurality of gas through holes are arranged in a circle in the first region of the pedestal plate.
